(19) United States
(12) Patent Application Publication
(10) Pub. No.: US 2024/0425979 A1
(43) Pub. Date: Dec. 26, 2024

(54) YTTRIUM-BASED PROTECTIVE FILM, METHOD FOR PRODUCING SAME, AND MEMBER

(71) Applicants: AGC Inc., Tokyo (JP); TSUBASA SCIENCE CORPORATION, Yokohama-shi (JP)

(72) Inventors: Michio ISHIKAWA, Kanagawa (JP); Michio TANIMURA, Kanagawa (JP); Shuhei OGAWA, Tokyo (JP); Tomonori OGAWA, Tokyo (JP)

(73) Assignees: AGC Inc., Tokyo (JP); TSUBASA SCIENCE CORPORATION, Yokohama-shi (JP)

(21) Appl. No.: 18/802,049

(22) Filed: Aug. 13, 2024

Related U.S. Application Data
(63) Continuation of application No. PCT/JP2023/005071, filed on Feb. 14, 2023.

(30) Foreign Application Priority Data
Feb. 18, 2022 (JP) 2022-024103

(51) Int. Cl. C23C 16/40; C23C 16/448

(52) U.S. Cl. CPC C23C 16/405; C23C 16/448

(57) ABSTRACT

The present invention relates to an yttrium-based protective film having: a peak intensity ratio of Y₅O₄F₇ in an X-ray diffraction pattern of 80% or more; a porosity of less than 1.5 volume %; and a Vickers hardness of 500 MPa or more. The yttrium-based protective film may have a content of fluorine of 35 atom % to 60 atom %.

### TECHNICAL FIELD

The present invention relates to an yttrium-based protective film, a method for producing the yttrium-based protective film, and a member.

### BACKGROUND ART

When a semiconductor device is produced, for example, a surface of a semiconductor substrate (silicon wafer) is microfabricated by dry etching using halogen-based gas plasmas in a chamber, and the chamber from which the semiconductor substrate is taken out after the dry etching is cleaned using oxygen gas plasmas.

At this time, a member exposed to the plasma gas in the chamber is corroded, and a corroded part may fall off in the form of particles from the corroded member. The fallen particles adhere to the semiconductor substrate and may become a foreign substance that causes a defect in a circuit.

In the related art, a protective film (yttrium-based protective film) containing yttrium oxyfluorides has been known as a protective film for protecting the member exposed to plasmas. Patent Literature 1 discloses a thermal sprayed coating that is formed by thermal spraying and contains yttrium oxyfluorides.

### CITATION LIST

### Patent Literature

Patent Literature 1: JP2018-76546A

### SUMMARY OF INVENTION

### Technical Problem

The present inventors have studied and found that the yttrium-based protective film in the related art may have insufficient plasma resistance (corrosion resistance against plasmas).

The present invention has been made in view of the above points, and an object thereof is to provide an yttrium-based protective film having excellent plasma resistance.

### Solution to Problem

As a result of intensive studies, the present inventors have found that the above object can be achieved by adopting the following configuration, and have completed the present invention.

That is, the present invention provides the following [1] to [14].

[1] An yttrium-based protective film having:
a peak intensity ratio of Y₅O₄F₇ in an X-ray diffraction pattern of 60% or more;
a porosity of less than 1.5 volume %; and
a Vickers hardness of 500 MPa or more.

[2] The yttrium-based protective film according to [1], in which a content of fluorine is 35 atom % to 60 atom %.

[3] The yttrium-based protective film according to [1] or [2], in which a crystallite size is 30 nm or less.

[4] The yttrium-based protective film according to any one of [1] to [3], having a thickness of 0.3 μm or more.

[5] The yttrium-based protective film according to any one of [1] to [4], in which a half width of a rocking curve of a (151) plane of Y₅O₄F₇ is 40° or less.

[6] A member including: a substrate; and the yttrium-based protective film according to any one of [1] to [5] disposed on a film formation surface that is a surface of the substrate.

[7] The member according to [6], in which the substrate includes at least one selected from the group consisting of ceramics and metal,
the ceramics is at least one selected from the group consisting of glass, quartz, aluminum oxide, aluminum nitride, and aluminum oxynitride, and
the metal is at least one selected from the group consisting of aluminum and an alloy containing aluminum.

[8] The member according to [6] or [7], in which the film formation surface has a surface roughness of 0.6 μm or less in terms of an arithmetic average roughness Ra.

[9] The member according to any one of [6] to [8], in which the film formation surface has a maximum length of 30 mm or more.

[10] The member according to any one of [6] to [9], further including at least one base layer between the substrate and the yttrium-based protective film, in which the base layer includes at least one kind of oxide selected from the group consisting of Al₂O₃, SiO₂, Y₂O₃, MgO, ZrO₂, La₂O₃, Nd₂O₃, Yb₂O₃, Eu₂O₃, and Gd₂O₃.

[11] The member according to [10], further including two or more of the base layers between the substrate and the yttrium-based protective film,
in which the oxides in the adjacent base layers are different from each other.

[12] The member according to any one of [6] to [11], in which the substrate has, as the film formation surface, a first film formation surface defining the maximum length and a second film formation surface different from the first film formation surface,
an angle formed by the first film formation surface and the second film formation surface is 20° to 120°, and
a proportion of an area of the second film formation surface to a total area of the film formation surfaces is 60% or less.

[13] The member according to any one of [6] to [12], which is used in a plasma etching apparatus or a plasma CVD apparatus.

[14] A method for producing the yttrium-based protective film according to any one of [1] to [5], the method including: causing an evaporation source to evaporate and adhere to the substrate while emitting ions of at least one kind of element selected from the group consisting of oxygen, argon, neon, krypton, and xenon in a vacuum,
in which Y₂O₃ and YF₃ are used as the evaporation source.

### Advantageous Effects of Invention

According to the present invention, an yttrium-based protective film having excellent plasma resistance can be provided.

### BRIEF DESCRIPTION OF DRAWINGS

FIG. 1 is a schematic diagram showing an example of a member.

FIG. 2 is a schematic diagram showing a ring-shaped substrate with a half cut away.

FIG. 3 is a schematic diagram showing a part of a cross section of another ring-shaped substrate.

FIG. 4 is a schematic diagram showing a part of a cross section of still another ring-shaped substrate.

FIG. 5 is a schematic diagram showing an apparatus used for producing an yttrium-based protective film.

### DESCRIPTION OF EMBODIMENTS

The terms used in the present invention have the following meanings.

A numerical range represented by using “to” means a range including numerical values described before and after “to” as a lower limit value and an upper limit value.

### [Yttrium-Based Protective Film]

An yttrium-based protective film according to the present embodiment has a peak intensity ratio of Y₅O₄F₇ in an X-ray diffraction pattern of 60% or more, a porosity of less than 1.5 volume %, and a Vickers hardness of 500 MPa or more.

Hereinafter, the yttrium-based protective film is also simply referred to as a “protective film”, and the yttrium-based protective film (protective film) according to the present embodiment is also referred to as “the present protective film”.

The yttrium-based protective film contains yttrium oxyfluorides.

Examples of a chemical formula representing yttrium oxyfluorides include YOF and Y₅O₄F₇. YOF is an orthorhombic crystal having a low hardness, whereas Y₅O₄F₇ has a special crystal structure called a rhombohedron and has a high hardness.

The present protective film has a large proportion of Y₅O₄F₇ having a rhombohedral crystal structure. That is, a peak intensity ratio of Y₅O₄F₇ in the X-ray diffraction pattern is equal to or larger than a certain value. Accordingly, the present protective film is hard and exhibits a Vickers hardness equal to or larger than a certain value.

Further, the present protective film is dense and has a low porosity when being formed by a method described below (the present production method).

The present protective film has excellent plasma resistance.

Hereinafter, the present protective film will be described in more detail.

### <Peak Intensity Ratio>

The peak intensity ratio of Y₅O₄F₇ in the X-ray diffraction pattern of the present protective film (hereinafter, also referred to as “Y₅O₄F₇ peak intensity ratio”) is 60% or more, preferably 80% or more, more preferably 90% or more, still more preferably 95% or more, yet still more preferably 98% or more, particularly preferably 99% or more, and most preferably 100%.

In order to keep the Y₅O₄F₇ peak intensity ratio within the above range, it is preferable to produce the protective film by the method described below (the present production method).

The Y₅O₄F₇ peak intensity ratio is a proportion (unit: %) of a main peak intensity of Y₅O₄F₇ when the total of the main peak intensities of crystal phases shown below is 100 in the X-ray diffraction (XRD) pattern of the protective film.

A peak of Y₆O₅F₈ crystal and a peak of Y₇O₆F₉ crystal appear in an overlapping manner at a main peak position of Y₅O₄F₇, and therefore, the possibility that trace amounts of Y₆O₅F₈ and Y₇O₆F₉ are generated cannot be excluded. However, all peaks located at the main peak position of Y₅O₄F₇ are treated as Y₅O₄F₇ peaks.

As for the main peak of each crystal phase, a main peak of Y₂O₃ appears in a vicinity of 2θ=29.2°, a main peak of YOF appears in a vicinity of 20-28.1°, and a main peak of Y₅O₄F₇ appears in a vicinity of 20=28.1°.

A main peak of YF₃ overlaps with that of Y₅O₄F₇, and therefore, when the YF₃ crystal is present, an intensity of a peak in a vicinity of 2θ=24.5°, which is a second main peak of the YF₃ crystal, is multiplied by 1.3 and converted to be equivalent to a main peak, and this peak intensity is defined as the main peak intensity of YF₃.

The XRD pattern of the protective film is obtained by performing an XRD measurement in a micro portion 2D (two-dimensional) mode using an X-ray diffractometer (D8 DISCOVER Plus, manufactured by Bruker) under the following conditions.
X-ray source: CuKα ray (output: 45 kV, current: 120 mA)
Scanning range: 2θ=10° to 80°
Step time: 0.2 s/step
Scan speed: 10°/min
Step width: 0.02° ·Detector: multi-mode detector EIGER (2D mode)
Incident side optical system: multilayer mirror+1.0 mmφ micro slit+1.0 mmφ collimator
Light receiving side optical system: OPEN

### <Vickers Hardness>

For the reason that the present protective film has excellent plasma resistance, the Vickers hardness of the present protective film is 500 MPa or more, preferably 800 MPa or more, more preferably 1000 MPa or more, still more preferably 1100 MPa or more, yet still more preferably 1200 MPa or more, particularly preferably 1250 MPa or more, and most preferably 1300 MPa or more.

An upper limit of the Vickers hardness of the present protective film is not particularly limited, and is, for example, 1500 MPa, and preferably 1400 MPa. That is, the Vickers hardness of the present protective film is, for example, 500 MPa to 1500 MPa.

In order to keep the Vickers hardness within the above range, it is preferable to keep the peak intensity ratio of Y₅O₄F₇ in the protective film within the above range.

The Vickers hardness of the protective film is determined in accordance with JIS R 1610:2003.

More specifically, the Vickers hardness is a Vickers hardness (Hv 0.2) determined using a hard microhardness tester (HMV-1, manufactured by Shimadzu Corporation) when a test force of 1.96 N is applied by a diamond indenter having a facing angle of 136°.

### <Porosity>

For the reason that the present protective film has excellent plasma resistance, the porosity of the present protective film is less than 1.5 volume %, preferably 1.0 volume % or less, more preferably 0.5 volume % or less, still more preferably 0.3 volume % or less, particularly preferably 0.2 volume % or less, and most preferably 0.1 volume % or less.

In order to keep the porosity within the above range, it is preferable to produce the protective film by the method described below (the present production method).

The porosity of the protective film is determined as follows.

First, a focused ion beam (FIB) is used to perform slope processing on a part of the protective film and a substrate described below in a thickness direction at an angle of 52° from a surface of the protective film toward the substrate to expose a cross section. The exposed cross section is observed at a magnification of 20000 times using a field emission scanning electron microscope (FE-SEM), and a cross-sectional image thereof is captured.

The cross-sectional image is captured at a plurality of locations. Specifically, for example, when the protective film and the substrate have a circular shape, images are captured at five points in total, one point at a center of the surface of the protective film (or a surface of the substrate) and four points at positions that are 10 mm away from the outer periphery, and a size of the cross-sectional image is 6 μm×5 μm. When a thickness of the protective film is 5 μm or more, cross-sectional images are respectively captured at a plurality of imaging positions so that the entire cross section of the protective film can be observed in the thickness direction.

Subsequently, an area of the pore portion in the cross-sectional image is specified by analyzing the obtained cross-sectional image using image analysis software (Image J, manufactured by National Institute of Health). A proportion of the area of the pore portion to the area of the entire cross section of the protective film is calculated and regarded as the porosity (unit: volume %) of the protective film. Regarding pores that are too fine to be detected by the image analysis software (pores with a pore diameter of 20 nm or less), areas thereof are regarded as 0.

### <Composition>

The present protective film contains yttrium (Y), oxygen (O), and fluorine (F) because the present protective film contains yttrium oxyfluorides.

### <<Content of Y>>

The content of Y in the present protective film is preferably 10 atom % to 35 atom %. Here, the content of Y in the present protective film is preferably 10 atom % or more, more preferably 20 atom % or more, still more preferably 25 atom % or more, particularly preferably 26 atom % or more, and most preferably 27 atom % or more.

On the other hand, the content of Y in the present protective film is preferably 35 atom % or less, more preferably 30 atom % or less, still more preferably 29 atom % or less, and particularly preferably 28 atom % or less.

### <<Content of O>>

The content of O in the present protective film is preferably 10 atom % to 35 atom %. Here, the content of O in the present protective film is preferably 10 atom % or more, more preferably 15 atom % or more, still more preferably 20 atom % or more, particularly preferably 21 atom % or more, and most preferably 22 atom % or more.

On the other hand, the content of O in the present protective film is preferably 35 atom % or less, more preferably 30 atom % or less, still more preferably 25 atom % or less, particularly preferably 24 atom % or less, and most preferably 23.5 atom % or less.

### <<Content of F>>

The content of F in the present protective film is preferably 35 atom % to 65 atom %.

Here, the content of F in the present protective film is preferably 35 atom % or more, more preferably 40 atom % or more, still more preferably 44 atom % or more, particularly preferably 47 atom % or more, and most preferably 49.5 atom % or more.

On the other hand, the content of F in the present protective film is preferably 65 atom % or less, more preferably 60 atom % or less, still more preferably 55 atom % or less, yet still more preferably 52 atom % or less, particularly preferably 51 atom % or less, and most preferably 50 atom % or less.

In order to keep the content of each element within the above range, for example, in the method described below (the present production method), production conditions such as the amount of the evaporation source are appropriately adjusted.

The content (unit: atom %) of each of Y, O, and F in the protective film is measured using an energy dispersive X-ray spectrometer (EX-250SE, manufactured by Horiba, Ltd.).

### <Degree of Orientation (Half Width of Rocking Curve)>

When the area of the protective film is increased, from the viewpoint of preventing the occurrence of cracks in the protective film, it is preferable that the degree of orientation of the (151) plane of Y₅O₄F₇ in the protective film (hereinafter, also simply referred to as “degree of orientation”) is high.

As an index of the degree of orientation, the half width of a rocking curve of the (151) plane of Y₅O₄F₇ is used. Specifically, the rocking curve of a peak of the (151) plane of Y₅O₄F₇, which is obtained by using a two-dimensional mode detector, is integrated in a 2θ direction, and the orientation is evaluated using the half width of the rocking curve. The smaller the half width (unit: °) is, the higher the degree of orientation is.

The half width of the rocking curve of the (151) plane of Y₅O₄F₇ is preferably 40° or less, more preferably 30° or less, still more preferably 25° or less, yet still more preferably 20° or less, particularly preferably 15° or less, and most preferably 10° or less.

In order to keep the degree of orientation within the above range, it is preferable to produce the protective film by the method described below (the present production method).

### <Crystallite Size>

As described above, for example, the particles falling off from the member exposed to the plasma gas may adhere to a semiconductor substrate and become a foreign substance causing a defect in a circuit.

At this time, as the sizes of the particles are small, the occurrence of defects can be prevented.

Therefore, the crystallite size of the present protective film is preferably 30 nm or less, more preferably 25 nm or less, still more preferably 20 nm or less, particularly preferably 15 nm or less, and most preferably 10 nm or less.

On the other hand, the lower limit of the crystallite size of the present protective film is not particularly limited, and is, for example, 2 nm, and preferably 5 nm. That is, the crystallite size of the present protective film is, for example, 2 nm to 30 nm.

In order to keep the crystallite size within the above range, it is preferable to produce the protective film by the method described below (the present production method).

The crystallite size of the protective film is determined using Scherrer's formula based on data of XRD pattern data obtained by the XRD measurement of the mirror-polished protective film.

### <Thickness>

The thickness of the present protective film is preferably 0.3 μm or more, more preferably 1 μm or more, still more preferably 5 μm or more, yet still more preferably 10 μm or more, particularly preferably 15 μm or more, and most preferably 20 μm or more.

The upper limit of the thickness of the present protective film is not particularly limited, and is, for example, 300 μm, preferably 200 μm, more preferably 100 μm, still more preferably 50 μm, and particularly preferably 30 μm. That is, the thickness of the present protective film is, for example, 0.3 μm to 300 μm.

The thickness of the protective film is measured as follows.

The cross section of the protective film is observed using a scanning electron microscope (SEM), the thickness of the protective film is measured at arbitrary five points, and an average value of the thickness of the measured five points is regarded as the thickness (unit: μm) of the protective film.

### <Thermal Conductivity>

The thermal conductivity of the present protective film is preferably 5.0 W/(m·K) or more, more preferably 7.0 W/(m·K) or more, still more preferably 9.0 W/(m·K) or more, particularly preferably 11.0 W/(m·K) or more, and most preferably 12.5 W/(m·K) or more.

The thermal conductivity of the protective film is determined at room temperature (23° C.) by a flash method using xenon lamp light of LFA 447 (Nanoflash) manufactured by NETZSCH.

Specifically, the bulk densities of the substrate and the protective film are determined based on the mass and the volume, and the specific heat capacities of the substrate and the protective film are determined by the differential scanning calorimetry defined in JIS R 1672:2006. Further, a multilayer analysis model is applied to a temperature rise curve obtained by the flash method to determine the thermal diffusivity of the substrate and the protective film. The thermal conductivity is determined based on a product of the bulk density, the specific heat capacity, and the thermal diffusivity.

### [Member]

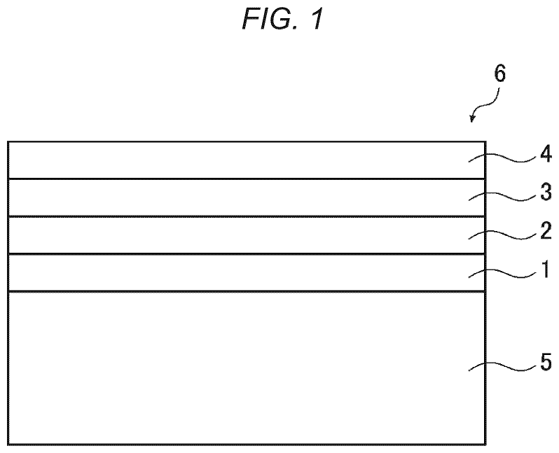

FIG. 1 is a schematic diagram showing an example of a member 6.

The member 6 includes a substrate 5 and an yttrium-based protective film 4.

As shown in FIG. 1, a base layer (a base layer 1, a base layer 2, and a base layer 3) may be disposed between the substrate 5 and the yttrium-based protective film 4. However, the number of the base layers is not limited to three.

The member according to the present embodiment (hereinafter, also referred to as “the present member”) has the present protective film described above, as the yttrium-based protective film.

The surface of the present member is covered with the present protective film, and therefore, the present member has excellent plasma resistance like the present protective film. Hereinafter, each part of the present member will be described in detail.

### <Substrate>

The substrate has at least a surface on which an yttrium-based protective film (or a base layer described below) is formed. Hereinafter, this surface may be referred to as a “film formation surface” for convenience.

### <<Material>>

A material of the substrate is appropriately selected depending on the use of the member or the like.

The substrate is formed of, for example, at least one selected from the group consisting of ceramics and metals.

Here, the ceramics are, for example, at least one selected from the group consisting of glass (soda lime glass or the like), quartz, aluminum oxide (Al₂O₃), aluminum nitride (AlN), and aluminum oxynitride (AlON).

The metals are, for example, at least one selected from the group consisting of aluminum and an alloy containing aluminum.

### <<Shape>>

The shape of the substrate is not particularly limited, and examples thereof include a flat plate shape, a ring shape, a dome shape, a protruding shape, and a recessed shape. The shape of the substrate is appropriately selected depending on the use of the member.

### <<Surface Roughness of Film Formation Surface>>

The surface roughness of the film formation surface of the substrate is, in terms of the arithmetic average roughness Ra, preferably 0.6 μm or less, more preferably 0.3 μm or less, still more preferably 0.1 μm or less, yet still more preferably 0.05 μm or less, particularly preferably 0.01 μm or less, and most preferably 0.005 μm or less, for reasons described below.

The surface roughness (arithmetic average roughness Ra) of the film formation surface is measured in accordance with JIS B 0601:2001.

### <<Area of Film Formation Surface>>

The area of the film formation surface of the substrate is not particularly limited, and is, for example, 200 cm² or more, and preferably 2000 cm² or more. The upper limit of the area of the film formation surface of the substrate is, for example, 10000 cm², and preferably 5000 cm².

### <<Maximum Length of Film Formation Surface>>

The maximum length of the film formation surface of the substrate is preferably 30 mm or more, more preferably 100 mm or more, still more preferably 200 mm or more, yet still more preferably 300 mm or more, particularly preferably 500 mm or more, very preferably 800 mm or more, and most preferably 1000 mm or more.

The term “maximum length” means the maximum length that the film formation surface has. Specifically, for example, when the film formation surface is a circle in plan view, the maximum length is the diameter of the circle. When the film formation surface is a ring in plan view, the maximum length is the outer diameter thereof. When the film formation surface is a rectangle in plan view, the maximum length is the length of the maximum diagonal line.

The upper limit of the maximum length of the film formation surface is not particularly limited, and is, for example, 2000 mm, and preferably 1500 mm. That is, the maximum length of the film formation surface is, for example, 30 mm to 2000 mm.

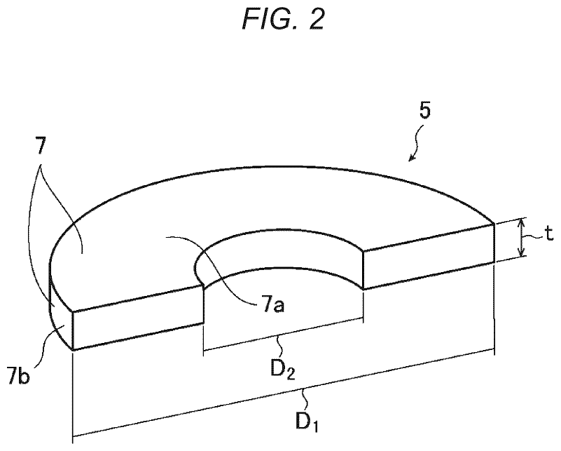

FIG. 2 is a schematic diagram showing a ring-shaped substrate 5 with a half cut away.

For example, when the substrate 5 shown in FIG. 2 has an outer diameter D1 of 100 mm, an inner diameter D2 of 90 mm, and a thickness t of 5 mm, the maximum length of the substrate 5 is 100 mm.

The substrate 5 has a film formation surface 7, and as shown in FIG. 2, the film formation surface 7 may have a first film formation surface 7a defining the maximum length (outer diameter D1) and a second film formation surface 7b different from the first film formation surface 7a.

A proportion of the area of the second film formation surface 7b to the total area of the film formation surface 7 is, for example, 60% or less.

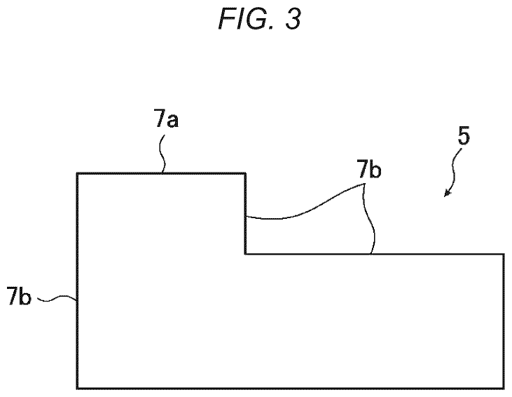

FIG. 3 is a schematic diagram showing a part of a cross section of another ring-shaped substrate 5.

As shown in FIG. 3, the substrate 5 may have a plurality of second film formation surfaces 7b.

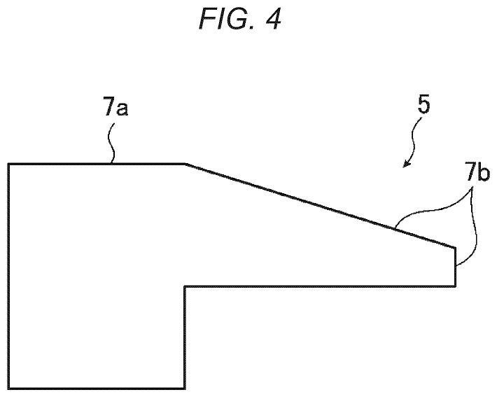

FIG. 4 is a schematic diagram showing a part of a cross section of still another ring-shaped substrate 5.

An angle formed by the first film formation surface 7a and the second film formation surface 7b is, for example, 20° to 120°. In the substrate 5 shown in FIG. 4, an angle formed by the first film formation surface 7a and the second film formation surface 7b connected to the first film formation surface 7a is about 30°.

### <Base Layer>

As described above, one or more base layers may be disposed between the substrate and the yttrium-based protective film.

By forming the base layer, the stress of the yttrium-based protective film is relaxed, or the adhesion of the yttrium-based protective film to the substrate is increased.

The upper limit of the number of the base layers is not particularly limited, and the number of the base layers is preferably 5 or less, more preferably 4 or less, still more preferably 3 or less, particularly preferably 2 or less, and most preferably 1.

The base layer is preferably an amorphous film or a microcrystalline film.

The base layer preferably contains at least one kind of oxide selected from the group consisting of Al₂O₃, SiO₂, Y₂O₃, MgO, ZrO₂. La₂O₃, Nd₂O₃, Yb₂O₃, Eu₂O₃, and Gd₂O₃.

When two or more base layers are disposed between the substrate and the yttrium-based protective film, the oxides in the base layers are preferably different from each other between the adjacent base layers.

Specific examples of the case where the oxides in the adjacent base layers are different from each other include a case where an oxide in a base layer 1 is “SiO₂”, an oxide in a base layer 2 is “Al₂O₃+SiO₂”, and an oxide in a base layer 3 is “Al₂O₃”.

The thickness of each base layer is preferably 0.1 μm or more, more preferably 0.4 μm or more, and still more preferably 0.8 μm or more.

On the other hand, the thickness of each base layer is, for example, 15 μm or less, preferably 10 μm or less, more preferably 7 μm or less, and still more preferably 3 μm or less. That is, the thickness of the each base layer is, for example, 0.1 μm to 15 μm.

The thickness of the base layer is measured in the same manner as the thickness of the yttrium-based protective film.

### <Use of Member>

The present member is used as, for example, a member such as a top plate in a semiconductor device producing apparatus (a plasma etching apparatus, a plasma CVD apparatus, or the like).

However, the use of the present member is not limited thereto.

### [Method for Producing Yttrium-Based Protective Film and Member]

Next, a method for producing the yttrium-based protective film according to the present embodiment (hereinafter, also referred to as “the present production method”) will be described. The present production method is also a method for producing the present member described above.

The present production method is a so-called ion assisted deposition (IAD) method.

Schematically, an evaporation source (Y₂O₃ and YF₃) is caused to evaporate and adhere to the substrate while emitting ions in a vacuum, thereby forming the yttrium-based protective film with a high proportion of Y₅O₄F₇.

According to the present production method, the yttrium-based protective film can be formed very densely. That is, the obtained yttrium-based protective film has a low porosity. The crystallite size is also small.

As the thickness of the yttrium-based protective film increases, cracks are more likely to occur.

When the area of the film formation surface increases, the area of the yttrium-based protective film formed on the film formation surface also increases. In this case, the yttrium-based protective film is also likely to crack.

However, according to the present production method, a dense and hard yttrium-based protective film can be obtained.

Furthermore, when the base layer is formed, the stress of the yttrium-based protective film is relaxed.

Therefore, the yttrium-based protective film obtained by the present production method is less likely to crack even if the thickness is increased or the area is increased.

The surface roughness (arithmetic average roughness Ra) of the film formation surface of the substrate is preferably within the above-described range. Accordingly, the formed yttrium-based protective film is denser and harder, and is less likely to crack.

In a method such as a thermal spraying method or an aerosol deposition (AD) method, a large number of pores are likely to remain in the obtained yttrium-based protective film.

In these methods, it may be difficult to control the fluorine content of the obtained yttrium-based protective film, and it may be difficult to stably obtain a desired composition.

In addition, examples of a method different from the IAD method include a sputtering method. In the sputtering method, for example, in a vacuum, plasmas of argon and oxygen are caused to collide with a sputtering target YOₓF_{y} to form a film on the substrate.

However, in this method, the fluorine content is likely to change, and it is difficult to stably form an yttrium-based protective film having a rhombohedral crystal structure and having a large proportion of Y₅O₄F₇.

### <Device Configuration>

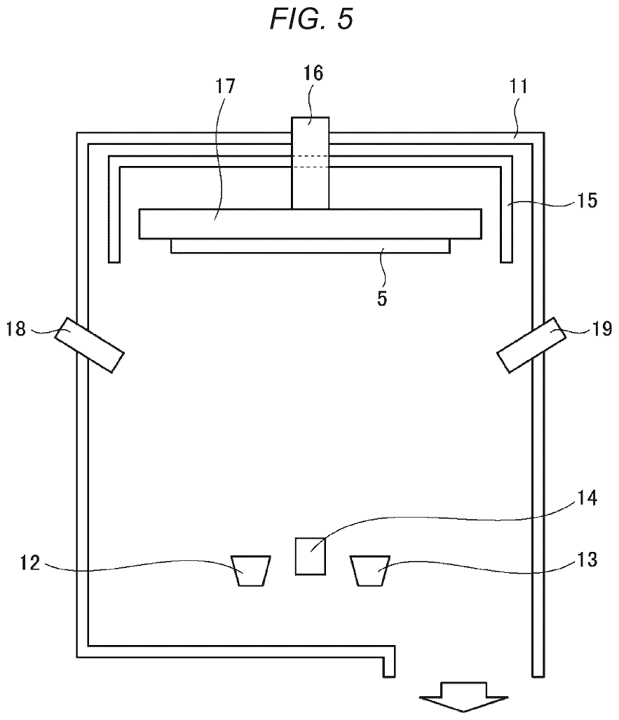

The present production method will be described in more detail with reference to FIG. 5.

FIG. 5 is a schematic diagram showing an apparatus used for producing the yttrium-based protective film.

The apparatus shown in FIG. 5 includes a chamber 11. A vacuum state can be formed inside the chamber 11 by driving a vacuum pump (not shown) to evacuate.

A crucible 12, a crucible 13, and an ion gun 14 are disposed inside the chamber 11, and a holder 17 is disposed above the crucible 12, the crucible 13, and the ion gun 14.

The holder 17 is integrated with a support shaft 16 and rotates with the rotation of the support shaft 16. A heater 15 is disposed around the holder 17.

The above-described substrate 5 is held by the holder 17 in a state in which the film formation surface of the substrate 5 faces downward. The substrate 5 held by the holder 17 rotates with the rotation of the holder 17 while being heated by the heater 15.

Further, a crystal type film thickness monitor 18 and a crystal type film thickness monitor 19 are attached to the chamber 11.

### <Formation of Yttrium-Based Protective Film>

A case where the yttrium-based protective film (not shown in FIG. 5) is formed on the substrate 5 in the apparatus shown in FIG. 5 will be described.

First, one crucible 12 is filled with an evaporation source Y₂O₃, and the other crucible 13 is filled with an evaporation source YF₃.

After the substrate 5 is held by the holder 17, the inside of the chamber 11 is evacuated to make a vacuum state. Specifically, the pressure inside the chamber 11 is preferably 8×10⁻² Pa or less.

Next, the holder 17 is rotated while driving the heater 15. Accordingly, the substrate 5 is rotated while being heated.

In this state, ion assisted deposition is performed to form a film on the substrate 5.

That is, the evaporation source Y₂O₃ in the crucible 12 and the evaporation source YF₃ in the crucible 13 are evaporated in parallel while emitting ions (ion beams) from the ion gun 14.

The ions emitted by the ion gun 14 are preferably ions of at least one kind of element selected from the group consisting of oxygen, argon, neon, krypton, and xenon.

The evaporation source melts and evaporates by being irradiated with electron beams (not shown).

In this way, the evaporated evaporation source adheres to the film formation surface of the substrate 5 to form an yttrium-based protective film.

### <<Internal Pressure of Chamber>>

The film formation is performed in the vacuum, and specifically, the internal pressure of the chamber 11 is preferably 8×10⁻² Pa or less, more preferably 6×10⁻² Pa or less, still more preferably 5×10⁻² Pa or less, and particularly preferably 3×10⁻² Pa or less.

The lower limit is preferably 0.5×10⁻² Pa. That is, the internal pressure of the chamber 11 is preferably 0.5×10⁻² Pa to 8×10⁻² Pa.

### <<Temperature of Substrate>>

In the film formation, the temperature of the substrate 5 heated by the heater 15 is preferably 200° C. or higher, and more preferably 250° C. or higher. On the other hand, the temperature is preferably 400° C. or lower, and more preferably 350° C. or lower. That is, the temperature of the substrate 5 is preferably 200° C. to 400° C.

### <<Film Formation Rate>>

The rate (film formation rate) at which a film is formed by evaporating the evaporation source in the crucible 12 is monitored in advance using the crystal type film thickness monitor 18.

In addition, the rate (film formation rate) at which a film is formed by evaporating the evaporation source in the crucible 13 is monitored in advance using the crystal type film thickness monitor 19.

The film formation rate is adjusted by controlling conditions of the electron beam emitted to the evaporation source and conditions (current value, current density, etc.) of the ion beam of the ion gun 14.

During the formation of the yttrium-based protective film, the film formation rate (unit: nm/min) of each evaporation source is adjusted to a desired value.

A film formation rate ratio (Y₂O₃/YF₃) of the film formation rate (unit: nm/min) of the evaporation source Y₂O₃ to the film formation rate (unit: nm/min) of the evaporation source YF₃ is preferably 7.5 to 1/1.1.

Here, the film formation rate ratio (Y₂O₃/YF₃) is preferably 1/9.5 or more, more preferably 1/8.0 or more, still more preferably 1/6.0 or more, and particularly preferably 1/4.5 or more.

On the other hand, the film formation rate ratio (Y₂O₃/YF₃) is preferably 1/1.1 or less, more preferably 1/1.3 or less, still more preferably 1/1.8 or less, and particularly preferably 1/2.5 or less.

A total of the film formation rate of the evaporation source Y₂O₃ and the film formation rate of the evaporation source YF₃ is preferably 5 nm/min to 50 nm/min.

Here, the total rate is preferably 5 nm/min or more, more preferably 8 nm/min or more, and still more preferably 10 nm/min or more. On the other hand, the total rate is preferably 50 nm/min or less, more preferably 35 nm/min or less, and still more preferably 20 nm/min or less.

### <<Conditions of Ion Irradiation>>

The distance between the ion gun 14 and the substrate 5 is preferably 700 mm to 1500 mm.

Here, the distance between the ion gun 14 and the substrate 5 is preferably 700 mm or more, and more preferably 900 mm or more. On the other hand, the distance is preferably 1500 mm or less, and more preferably 1300 mm or less.

The ion beam current value is preferably 1000 mA to 3000 mA.

Here, the ion beam current value is preferably 1000 mA or more, and more preferably 1500 mA or more.

On the other hand, the ion beam current value is preferably 3000 mA or less, and more preferably 2500 mA or less.

The ion beam current density is preferably 40 μA/cm² to 140 μA/cm².

Here, the ion beam current value is preferably 40 μA/cm² or more, more preferably 65 μA/cm² or more, still more preferably 75 μA/cm² or more, and particularly preferably 85 HA/cm² or more.

On the other hand, the ion beam current density is preferably 140 μA/cm² or less, and more preferably 120 μA/cm² or less.

### <Formation of Base Layer>

Before the yttrium-based protective film is formed, the above base layer (for example, the base layer 1, the base layer 2, and the base layer 3) is preferably formed on the film formation surface of the substrate 5.

Similarly to the yttrium-based protective film, the base layer is formed by ion assisted deposition.

For example, in the case where a base layer made of Al₂O₃ is formed, the crucible 12 and/or the crucible 13 are/is filled with Al₂O₃ as an evaporation source, and the evaporation source is evaporated while emitting ions (ion beams) from the ion gun 14 to adhere the evaporation source to the film formation surface of the substrate 5.

Conditions for forming the base layer conform to the conditions for forming the yttrium-based protective film.

### EXAMPLES

Hereinafter, the present invention will be specifically described with reference to Examples. However, the present invention is not limited to Examples described below.

Hereinafter, Examples 1 to 20 are Inventive Examples, Examples 21 to 27 are Comparative Examples, and Examples 28 to 30 are Reference Examples.

### Examples 1 to 27

An yttrium-based protective film (protective film) was produced using the apparatus described based on FIG. 5.

More specifically, under the production conditions shown in the following Tables 1 to 3, base layers and protective films shown in the following Tables 1 to 3 were each formed on a film formation surface of a substrate.

As the substrate, a circular substrate (thickness: 10 mm) having a film formation surface with a diameter (maximum length) of 200 mm was used. The composition of the protective film is determined based on the content of each element (Y, O, F, etc.).

As the production conditions not shown in the following Tables 1 to 3, oxygen (O) ions were emitted from the ion gun, the distance between the ion gun and the substrate was 1100 mm, and the ion beam current value was 2000 mA.

In Example 12, a commercially available soda lime glass was used as the substrate (glass).

In Example 14, one surface side of an aluminum substrate was subjected to alumite treatment to form a base layer made of Al₂O₃. This base layer is described as “alumite” in the following Table 2.

### Examples 28 to 30

In Example 28, sapphire was used as the protective film.

In Example 29, metallic aluminum was used as the protective film.

In Example 30, quartz was used as the protective film.

The thickness, Vickers hardness, and presence or absence of cracks of the protective film of each of Examples 28 to 30 are not evaluated.

### <Etching Amount>

Regarding the protective film of each example, the etching amount was determined to evaluate the plasma resistance.

Specifically, a 10 mm×5 mm surface of the protective film was mirror-finished. A Kapton tape was applied as a mask to a part of the mirror-finished surface, and etching was performed with plasma gas. Thereafter, the etching amount was determined by measuring a difference between the etched portion and the non-etched portion by using a stylus surface profiler (Dectak 150, manufactured by ULVAC, Inc.).

As a plasma etching apparatus, EXAM (model: POEM, manufactured by SHINKO SEIKI CO., LTD.) was used. In the RIE mode (reactive ion etching mode), first, under a pressure of 10 Pa and an output of 350 W, etching was performed for 180 minutes using a gas obtained by mixing CF₄ gas (flow rate: 100 sccm) and O₂ gas (flow rate: 10 sccm). Next, etching was performed for 180 minutes using CF₄ gas (flow rate: 100 sccm). Thereafter, etching was performed for 180 minutes using gas obtained by mixing CF₄ gas (flow rate: 100 sccm) and O₂ gas (flow rate: 10 sccm), and finally, etching was performed for 180 minutes using CF₄ gas (flow rate: 100 sccm).

As the etching amount (unit: nm) is smaller, it can be evaluated to have better plasma resistance.

Specifically, when the etching amount was 200 nm or less, the plasma resistance was evaluated to be excellent.

### <F Content Change Amount>

After the etching, the F content of the protective film was measured, and the F content change amount (unit: atom %) was determined based on the following formula.

F content change amount={(F content before etching)−(F content after etching)}/(F content before etching)

As a value of the F content change amount is smaller, the protective film can be evaluated as a stabilized protective film excellent in plasma resistance. Specifically, the F content change amount is preferably 10 atom % or less, more preferably 5 atom % or less, and still more preferably 3 atom % or less.

### <Presence or Absence of Cracks>

After the formation of the protective film, whether there were visually recognizable cracks in the protective film was checked. The following Tables 1 to 3 describe that the case where there were no cracks was evaluated as “Absent”, and the case where there were cracks was evaluated as “Present”.

TABLE 1

| | | | Ex. 1 | Ex. 2 | Ex. 3 | Ex. 4 | Ex. 5 |
|---|---|---|---|---|---|---|---|
| Production | Internal pressure of | | 1 × 10⁻² | 1 × 10⁻² | 1 × 10⁻² | 1 × 10⁻² | 1 × 10⁻² |
| conditions | chamber [Pa] | | | | | | |
| | Temperature (° C.) | | 300 | 300 | 300 | 300 | 300 |
| | of substrate | | | | | | |
| | Y₂O₃ | Evaporation | 3.42 | 6.78 | 1.92 | 1.8 | 3.42 |
| | YF₃ | source film | 11.88 | 8.76 | 13.36 | 15.3 | 10.59 |
| | | formation rate | | | | | |
| | | [nm/min] | | | | | |
| | Ion beam current | | 96 | 96 | 96 | 96 | 80 |
| | density [μA/cm²] | | | | | | |
| Substrate | Material | | Al₂O₃ | Al₂O₃ | Al₂O₃ | Al₂O₃ | Al₂O₃ |
| | Film | Ra [μm] | 0.03 | 0.03 | 0.03 | 0.03 | 0.03 |
| | formation | Area [cm²] | 314.2 | 314.2 | 314.2 | 314.2 | 314.2 |
| | surface | Maximum | 200 | 200 | 200 | 200 | 200 |
| | | length [mm] | | | | | |
| Base | 1 | Composition | Al₂O₃ | Al₂O₃ | Al₂O₃ | Al₂O₃ | Al₂O₃ |
| layer | | Thickness [μm] | 1 | 1 | 1 | 1 | 1 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Protective | Composition | | Y₅O_{4.2}F_{9.1} | Y₅O_{4.3}F_{8.7} | Y₅O_{4.3}F_{9.6} | Y₅O_{2.8}F_{12.9} | Y₅O_{4.1}F_{9.0} |
| film | Content | Y [atom %] | 27.2 | 27.8 | 26.5 | 24.1 | 27.6 |
| | | O [atom %] | 23.1 | 23.9 | 22.7 | 13.6 | 22.7 |
| | | F [atom %] | 49.7 | 48.3 | 50.8 | 62.3 | 49.7 |
| | | Al [atom %] | — | — | — | — | — |
| | | Si [atom %] | — | — | — | — | — |
| | | Others [atom %] | — | — | — | — | — |

| | | | | | |
|---|---|---|---|---|---|
| Y₅O₄F₇ peak | 100 | 100 | 95.4 | 89.6 | 100 |
| intensity ratio [%] | | | | | |
| Vickers hardness [MPa] | 1320 | 1290 | 1120 | 502 | 950 |
| Porosity [volume %] | 0.06 | 0.11 | 0.16 | 0.31 | 0.3 |
| Half width [°] of | 20.1 | 10.0 | 15.4 | 17.5 | 17.4 |
| rocking curve | | | | | |
| Thickness [μm] | 15.4 | 14.3 | 10.4 | 9.51 | 10.5 |
| Etching amount [nm] | 74 | 78 | 95 | 195 | 125 |
| F content change | 2.3 | 2.5 | 3.4 | 8.4 | 2.5 |
| amount [atom %] | | | | | |
| Presence or absence of cracks | Absent | Absent | Absent | Absent | Absent |

| | | | Ex. 6 | Ex. 7 | Ex. 8 | Ex. 9 | Ex. 10 |
|---|---|---|---|---|---|---|---|
| Production | Internal pressure of | | 1 × 10⁻² | 1 × 10⁻² | 1 × 10⁻² | 1 × 10⁻² | 1 × 10⁻² |
| conditions | chamber [Pa] | | | | | | |
| | Temperature (° C.) | | 300 | 300 | 300 | 300 | 300 |
| | of substrate | | | | | | |
| | Y₂O₃ | Evaporation | 3.42 | 3.42 | 3.42 | 3.42 | 3.42 |
| | YF₃ | source film | 11.88 | 11.88 | 11.88 | 11.88 | 11.88 |
| | | formation rate | | | | | |
| | | [nm/min] | | | | | |
| | Ion beam current | | 96 | 96 | 96 | 96 | 96 |
| | density [μA/cm²] | | | | | | |
| Substrate | Material | | Al₂O₃ | Al₂O₃ | Al₂O₃ | Al₂O₃ | Quartz |
| | Film | Ra [μm] | 0.03 | 0.05 | 0.1 | 0.5 | 0.02 |
| | formation | Area [cm²] | 314.2 | 314.2 | 314.2 | 314.2 | 314.2 |
| | surface | Maximum | 200 | 200 | 200 | 200 | 200 |
| | | length [mm] | | | | | |
| Base | 1 | Composition | — | — | — | — | SiO₂ |
| layer | | Thickness [μm] | — | — | — | — | 0.5 |
| | 2 | Composition | — | — | — | — | Al₂O₃ + |
| | | | | | | | SiO₂ |
| | | Thickness [μm] | — | — | — | — | 1 |
| | 3 | Composition | — | — | — | — | — |
| | | Thickness [μm] | — | — | — | — | — |
| Protective | Composition | | Y₅O_{4.2}F_{9.1} | Y₅O_{4.2}F_{9.1} | Y₅O_{4.2}F_{9.1} | Y₅O_{4.2}F_{9.1} | Y₅O_{4.2}F_{9.1} |
| film | Content | Y [atom %] | 27.2 | 27.2 | 27.2 | 27.2 | 27.2 |
| | | O [atom %] | 23.1 | 23.1 | 23.1 | 23.1 | 23.1 |
| | | F [atom %] | 49.7 | 49.7 | 49.7 | 49.7 | 49.7 |
| | | Al [atom %] | — | — | — | — | — |
| | | Si [atom %] | — | — | — | — | — |
| | | Others [atom %] | — | — | — | — | — |

| | | | | | |
|---|---|---|---|---|---|
| Y₅O₄F₇ peak | 100 | 100 | 100 | 100 | 100 |
| intensity ratio [%] | | | | | |
| Vickers hardness [MPa] | 1280 | 1250 | 1102 | 986 | 1210 |
| Porosity [volume %] | 0.45 | 0 | 0.22 | 0.68 | 0.22 |
| Half width [°] of | 19.8 | 21.3 | 31.2 | 38.7 | 17.5 |
| rocking curve | | | | | |
| Thickness [μm] | 13.2 | 15.2 | 0.9 | 12.9 | 10.4 |
| Etching amount [nm] | 82 | 120 | 195 | 197 | 73 |
| F content change | 2.3 | 2.5 | 2.2 | 2.4 | 2.4 |
| amount [atom %] | | | | | |
| Presence or absence of cracks | Absent | Absent | Absent | Absent | Absent |

TABLE 2

| | | | Ex. 11 | Ex. 12 | Ex. 13 | Ex. 14 | Ex. 15 |
|---|---|---|---|---|---|---|---|
| Production | Internal pressure of | | 1 × 10⁻² | 1 × 10⁻² | 1 × 10⁻² | 1 × 10⁻² | 1 × 10⁻² |
| conditions | chamber [Pa] | | | | | | |
| | Temperature (° C.) | | 300 | 300 | 300 | 300 | 300 |
| | of substrate | | | | | | |
| | Y₂O₃ | Evaporation | 6.78 | 3.42 | 3.42 | 3.42 | 3.42 |
| | YF₃ | source film | 8.76 | 11.88 | 11.88 | 11.88 | 11.88 |
| | | formation rate | | | | | |
| | | [nm/min] | | | | | |
| | Ion beam current | | 96 | 96 | 96 | 96 | 96 |
| | density [μA/cm²] | | | | | | |
| Substrate | Material | | Quartz | Glass | Al | Al | AlN |
| | Film | Ra [μm] | 0.02 | 0.03 | 0.09 | 0.09 | 0.04 |
| | formation | Area [cm²] | 314.2 | 314.2 | 314.2 | 314.2 | 314.2 |
| | surface | Maximum | 200 | 200 | 200 | 200 | 200 |
| | | length [mm] | | | | | |
| Base | 1 | Composition | SiO₂ | SiO₂ | Al₂O₃ | Alumite | Al₂O₃ |
| layer | | Thickness [μm] | 0.5 | 0.5 | 1 | 12 | 1 |
| | 2 | Composition | Al₂O₃ + | Al₂O₃ + | — | Al₂O₃ | — |
| | | | SiO₂ | SiO₂ | | | |
| | | Thickness [μm] | 1 | 1 | — | 1 | — |
| | 3 | Composition | — | Al₂O₃ | — | — | — |
| | | Thickness [μm] | — | 1 | — | — | — |
| Protective | Composition | | Y₅O_{4.3}F_{8.7} | Y₅O_{4.2}F_{9.1} | Y₅O_{4.2}F_{9.1} | Y₅O_{4.2}F_{9.1} | Y₅O_{4.2}F_{9.1} |
| film | Content | Y [atom %] | 27.8 | 27.2 | 27.2 | 27.2 | 27.2 |
| | | O [atom %] | 23.9 | 23.1 | 23.1 | 23.1 | 23.1 |
| | | F [atom %] | 48.3 | 49.7 | 49.7 | 49.7 | 49.7 |
| | | Al [atom %] | — | — | — | — | — |
| | | Si [atom %] | — | — | — | — | — |
| | | Others [atom %] | — | — | — | — | — |
| | Y₅O₄F₇ peak | | 100 | 100 | 94.3 | 100 | 100 |
| | intensity ratio [%] | | | | | | |
| | Vickers hardness [MPa] | | 1130 | 1150 | 980 | 1180 | 1260 |
| | Porosity [volume %] | | 0.21 | 0 | 0.18 | 0.32 | 0.49 |
| | Half width [°] of | | 10.9 | 21.2 | 28.5 | 27.3 | 16.7 |
| | rocking curve | | | | | | |
| | Thickness [μm] | | 10.3 | 15.3 | 4.2 | 11.3 | 10.3 |
| | Etching amount [nm] | | 74 | 86 | 95 | 85 | 74 |
| | F content change | | 2.6 | 2.2 | 2.3 | 2.6 | 2.2 |
| | amount [atom %] | | | | | | |
| | Presence or absence of cracks | | Absent | Absent | Absent | Absent | Absent |
| | | | Ex. 16 | Ex. 17 | Ex. 18 | Ex. 19 | Ex. 20 |
| Production | Internal pressure of | | 1 × 10⁻² | 1 × 10⁻² | 1 × 10⁻² | 1 × 10⁻² | 1 × 10⁻² |
| conditions | chamber [Pa] | | | | | | |
| | Temperature (° C.) | | 300 | 300 | 300 | 300 | 300 |
| | of substrate | | | | | | |
| | Y₂O₃ | Evaporation | 3.42 | 3.42 | 3.42 | 6.78 | 6.78 |
| | YF₃ | source film | 11.88 | 11.88 | 11.88 | 8.76 | 8.76 |
| | | formation rate | | | | | |
| | | [nm/min] | | | | | |
| | Ion beam current | | 96 | 96 | 96 | 96 | 96 |
| | density [μA/cm²] | | | | | | |
| Substrate | Material | | Al₂O₃ | Al₂O₃ | Al₂O₃ | Al₂O₃ | Al₂O₃ |
| | Film | Ra [μm] | 0.02 | 0.02 | 0.02 | 0.03 | 0.03 |
| | formation | Area [cm²] | 314.2 | 314.2 | 7853.8 | 314.2 | 314.2 |
| | surface | Maximum | 200 | 200 | 1000 | 200 | 200 |
| | | length [mm] | | | | | |
| Base | 1 | Composition | Al₂O₃ | Al₂O₃ | Al₂O₃ | — | Al₂O₃ |
| layer | | Thickness [μm] | 1 | 1 | 1 | — | 1 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Protective | Composition | | Y₅O_{4.2}F_{9.1} | Y₅O_{4.2}F_{9.1} | Y₅O_{4.2}F_{9.1} | Y₅O_{4.0}F_{6.9} | Y₅O_{4.0}F_{7.3} |
| film | Content | Y [atom %] | 27.2 | 27.2 | 27.2 | 31.5 | 30.7 |
| | | O [atom %] | 23.1 | 23.1 | 23.1 | 25 | 24.5 |
| | | F [atom %] | 49.7 | 49.7 | 49.7 | 43.5 | 44.8 |
| | | Al [atom %] | — | — | — | — | — |
| | | Si [atom %] | — | — | — | — | — |
| | | Others [atom %] | — | — | — | — | — |

| | | | | | |
|---|---|---|---|---|---|
| Y₅O₄F₇ peak | 100 | 100 | 100 | 100 | 100 |
| intensity ratio [%] | | | | | |
| Vickers hardness [MPa] | 1330 | 1220 | 1315 | 1300 | 1320 |
| Porosity [volume %] | 0.09 | 0.07 | 0.19 | 0 | 0 |
| Half width [°] of | 29.2 | 11.6 | 19.5 | 10.0 | 10.3 |
| rocking curve | | | | | |
| Thickness [μm] | 203 | 1.3 | 10.3 | 14.3 | 14.2 |
| Etching amount [nm] | 73 | 87 | 75 | 75 | 78 |
| F content change | 2.3 | 2.5 | 2.4 | 2.5 | 2.5 |
| amount [atom %] | | | | | |
| Presence or absence of cracks | Absent | Absent | Absent | Absent | Absent |

TABLE 3

| | | | Ex. 21 | Ex. 22 | Ex. 23 | Ex. 24 | Ex. 25 |
|---|---|---|---|---|---|---|---|
| Production | Internal pressure of | | 1 × 10⁻² | 1 × 10⁻² | 1 × 10⁻² | 1 × 10⁻² | 1 × 10⁻² |
| conditions | chamber [Pa] | | | | | | |
| | Temperature (° C.) | | 300 | 300 | 300 | 300 | 300 |
| | of substrate | | | | | | |
| | Y₂O₃ | Evaporation | 13.2 | 6.78 | 3.42 | 10.3 | 3.42 |
| | YF₃ | source film | 0 | 8.76 | 11.88 | 4.3 | 11.88 |
| | | formation rate | | | | | |
| | | [nm/min] | | | | | |
| | Ion beam current | | 96 | 24 | 96 | 96 | 96 |
| | density [μA/cm²] | | | | | | |
| Substrate | Material | | Al₂O₃ | Al₂O₃ | Al₂O₃ | Al₂O₃ | Al₂O₃ |
| | Film | Ra [μm] | 0.03 | 0.03 | 0.03 | 0.03 | 1.5 |
| | formation | Area [cm²] | 314.2 | 314.2 | 314.2 | 314.2 | 314.2 |
| | surface | Maximum | 200 | 200 | 200 | 200 | 200 |
| | | length [mm] | | | | | |
| Base | 1 | Composition | Al₂O₃ | Al₂O₃ | Al₂O₃ | Al₂O₃ | Al₂O₃ |
| layer | | Thickness [μm] | 1 | 1 | 1 | 1 | 1 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Protective | Composition | | Y₂O_{2.8} | Y₅O_{3.9}F_{8.3} | Y₅O_{4.0}F_{8.9} | Y₂O_{2.3}F_{2.1} | Y₅O_{4.2}F_{9.1} |
| film | Content | Y [atom %] | 42 | 29.1 | 27.9 | 31.3 | 27.2 |
| | | O [atom %] | 58 | 22.6 | 22.4 | 35.9 | 23.1 |
| | | F [atom %] | 0 | 48.3 | 49.7 | 32.8 | 49.7 |
| | | Al [atom %] | — | — | — | — | — |
| | | Si [atom %] | — | — | — | — | — |
| | | Others [atom %] | — | — | — | — | — |

| | | | | | |
|---|---|---|---|---|---|
| Y₅O₄F₇ peak | — | — | 91.4 | 25.5 | 93.7 |
| intensity ratio [%] | | | | | |
| Vickers hardness [MPa] | 1120 | 412 | 630 | 498 | 494 |
| Porosity [volume %] | 0.12 | 0 | 1.8 | 0 | 1.57 |
| Half width [°] of | — | — | 40.3 | 42.2 | 40.2 |
| rocking curve | | | | | |
| Thickness [μm] | 11.3 | 12.1 | 18.7 | 10.2 | 12.1 |
| Etching amount [nm] | 204 | 241 | 204 | 539 | 238 |
| F content change | 25.1 | 3.1 | 2.7 | 5.2 | 2.6 |
| amount [atom %] | | | | | |
| Presence or absence of cracks | Absent | Absent | Absent | Absent | Present |

| | | | Ex. 26 | Ex. 27 | Ex. 28 | Ex. 29 | Ex. 30 |
|---|---|---|---|---|---|---|---|
| Production | Internal pressure of | | 1 × 10⁻² | 1 × 10⁻² | — | — | — |
| conditions | chamber [Pa] | | | | | | |
| | Temperature (° C.) | | 300 | 300 | — | — | — |
| | of substrate | | | | | | |
| | Y₂O₃ | Evaporation | 8.35 | 3.42 | — | — | — |
| | YF₃ | source film | 7.22 | 11.88 | — | — | — |
| | | formation rate | | | | | |
| | | [nm/min] | | | | | |
| | Ion beam current | | 96 | 96 | — | — | — |
| | density [μA/cm²] | | | | | | |
| Substrate | Material | | Al₂O₃ | Al₂O₃ | — | — | — |
| | Film | Ra [μm] | 0.03 | 0.8 | — | 0.091 | — |
| | formation | Area [cm²] | 314.2 | 7853.8 | 314.2 | 314.2 | 314.2 |
| | surface | Maximum | 200 | 1000 | 200 | 200 | 200 |
| | | length [mm] | | | | | |
| Base | 1 | Composition | Al₂O₃ | Al₂O₃ | — | — | — |
| layer | | Thickness [μm] | 1 | 1 | — | — | — |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Protective | Composition | | Y₅O_{4.5}F_{5.5} | Y₅O_{4.2}F_{9.1} | — | — | — |
| film | Content | Y [atom %] | 22.3 | 27.2 | — | — | — |
| | | O [atom %] | 20.1 | 23.1 | — | — | 66.6 |
| | | F [atom %] | 57.6 | 49.7 | — | — | — |
| | | Al [atom %] | — | — | 40 | 100 | — |
| | | Si [atom %] | — | — | — | — | 33.3 |
| | | Others [atom %] | — | — | — | — | — |

| | | | | | |
|---|---|---|---|---|---|
| Y₅O₄F₇ peak | 59.2 | 88.5 | — | — | — |
| intensity ratio [%] | | | | | |
| Vickers hardness [MPa] | 420 | 466 | — | — | — |
| Porosity [volume %] | 0 | 1.68 | 0 | 0 | 0 |
| Half width [°] of | 35.4 | 36.7 | — | — | — |
| rocking curve | | | | | |
| Thickness [μm] | 11.3 | 23.4 | — | — | — |
| Etching amount [nm] | 203 | 206 | 781 | 8700 | 15900 |
| F content change | 6.2 | 2.6 | 29.4 | 36.1 | 3.1 |
| amount [atom %] | | | | | |
| Presence or absence of cracks | Absent | Present | — | — | — |

### <Summary of Evaluation Results>

As shown in Tables 1 to 3, it was found that the yttrium-based protective films of Examples 1 to 20 had excellent plasma resistance. In contrast, the yttrium-based protective films of Examples 21 to 27 had insufficient plasma resistance.

Although the embodiments of the present invention have been described above, the embodiment is not limited to the contents of these embodiments. In addition, the components described above should include those that can be easily conceived by a person skilled in the art, those that are substantially the same, and those within a so-called equivalent range. Further, the above components can be appropriately combined. Further, various omissions, substitutions, or modifications of the components can be made without departing from the gist of the embodiment described above.

The present application is based on a Japanese Patent Application (Japanese Patent Application No. 2022-024103) filed on Feb. 18, 2022, and the contents thereof are incorporated herein by reference.

### REFERENCE SIGNS LIST

1, 2, 3: base layer
4: yttrium-based protective film
5: substrate
6: member
7: film formation surface
7a: first film formation surface
7b: second film formation surface
11: chamber
12, 13: crucible
14: ion gun
15: heater
16: support shaft
17: holder
18, 19: crystal type film thickness monitor

1. An yttrium-based protective film having:
a peak intensity ratio of Y₅O₄F₇ in an X-ray diffraction pattern of 80% or more;
a porosity of less than 1.5 volume %; and
a Vickers hardness of 500 MPa or more.

2. The yttrium-based protective film according to claim 1, wherein a content of fluorine is 35 atom % to 60 atom %.

3. The yttrium-based protective film according to claim 1, wherein a crystallite size is 30 nm or less.

4. The yttrium-based protective film according to claim 1, having a thickness of 0.3 μm or more.

5. The yttrium-based protective film according to claim 1, wherein a half width of a rocking curve of a (151) plane of Y₅O₄F₇ is 40° or less.

6. A member comprising:
a substrate; and
the yttrium-based protective film according to claim 1 disposed on a film formation surface that is a surface of the substrate.

7. The member according to claim 6,
wherein the substrate comprises at least one selected from the group consisting of ceramics and metal,
the ceramics is at least one selected from the group consisting of glass, quartz, aluminum oxide, aluminum nitride, and aluminum oxynitride, and
the metal is at least one selected from the group consisting of aluminum and an alloy containing aluminum.

8. The member according to claim 6, wherein the film formation surface has a surface roughness of 0.6 μm or less in terms of an arithmetic average roughness Ra.

9. The member according to claim 6, wherein the film formation surface has a maximum length of 30 mm or more.

10. The member according to claim 6, further comprising at least one base layer between the substrate and the yttrium-based protective film,
wherein the base layer comprises at least one kind of oxide selected from the group consisting of Al₂O₃, SiO₂, Y₂O₃, MgO, ZrO₂, La₂O₃, Nd₂O₃, Yb₂O₃, Eu₂O₃, and Gd₂O₃.

11. The member according to claim 10, further comprising two or more of the base layers between the substrate and the yttrium-based protective film,
wherein the oxides in the adjacent base layers are different from each other.

12. The member according to claim 6,
wherein the substrate has, as the film formation surface, a first film formation surface defining the maximum length and a second film formation surface different from the first film formation surface,
an angle formed by the first film formation surface and the second film formation surface is 20° to 120°, and
a proportion of an area of the second film formation surface to a total area of the film formation surfaces is 60% or less.

13. The member according to claim 6, which is used in a plasma etching apparatus or a plasma CVD apparatus.

14. A method for producing the yttrium-based protective film according to claim 1, the method comprising:
causing an evaporation source to evaporate and adhere to the substrate while emitting ions of at least one kind of element selected from the group consisting of oxygen, argon, neon, krypton, and xenon in a vacuum,
wherein Y₂O₃ and YF₃ are used as the evaporation source.
